(19) United States
(12) Patent Application Publication
(10) Pub. No.: US 2024/0030063 A1
(43) Pub. Date: Jan. 25, 2024

(54) THERMALLY DECOMPOSABLE FILL MATERIAL

(71) Applicant: Brewer Science, Inc., Rolla, MO (US)

(72) Inventors: Daniel Patrick Sweat, Rolla, MO (US); Shannon Brown, Cuba, MO (US); Joyce A. Lowes, Rosebud, MO (US)

(21) Appl. No.: 18/354,433

(22) Filed: Jul. 18, 2023

Related U.S. Application Data
(60) Provisional application No. 63/390,567, filed on Jul. 19, 2022.

(51) Int. Cl. H01L 21/768; G03F 7/027; H01L 23/528

(52) U.S. Cl. CPC H01L 21/76837; G03F 7/027; H01L 21/7682; H01L 23/5283

(57) ABSTRACT

Thermally decomposable gap-fill materials are disclosed that fill small features and are completely removed by a high-temperature bake after processing. These materials are self-crosslinkable polymers. Potential applications of these materials include use as sacrificial gap-fill materials for creating air gaps, as well as protection of high-aspect-ratio or other delicate microelectronic features during processing steps.

### CROSS-REFERENCE TO RELATED APPLICATIONS

The present application claims the priority benefit of U.S. Provisional Patent Application Ser. No. 63/390,567, filed Jul. 19, 2022, entitled THERMALLY DECOMPOSABLE FILL MATERIAL, the entirety of which is incorporated by reference herein.

### BACKGROUND

### Field

The present disclosure relates to methods of fabricating microelectronic structures.

### Description of Related Art

As feature sizes become smaller and smaller according to Moore's law, photolithography of semiconductor devices has moved to multilayer patterning. This method involves patterning multiple layers on top of each other, such as a photoresist layer on top of a hardmask layer on top of a spin-on-carbon (“SOC”) layer, in order to increase the etch resistance for smaller features. As each layer is deposited and patterned, depositing a uniform, planarizing layer of material on top of it becomes critical for accurate pattern transfer and critical dimension (“CD”) control.

As these layers and features are built up on the substrate, there are often high-aspect-ratio trenches and gaps on the surface on the substrate. In some cases, sacrificial gap-fill materials may be used to fill those trenches and gaps during various lithography processes to prevent pattern collapse or other failure modes. After processing, those sacrificial gap-fill materials may be removed via a dry process (e.g., plasma etch) or a wet process (e.g., wet etch, solvent strip, develop out, photo expose plus solvent/develop removal). However, these traditional methods are not easily adaptable to generate an air gap, in those processes that benefit from air gap formation.

Historically, thermal decomposition of sacrificial gap-fill materials has been avoided due to byproduct generation, outgassing products collecting in the bake unit or exhaust lines, incomplete removal due to limited hotplate ranges, and other potential issues. Now that high temperature hotplates and track-based modules designed with high exhaust are more widely available, acceptance of this type of material is moving forward, but suitable materials and processes have not yet been developed.

### SUMMARY

The present disclosure is concerned with a gap-fill method comprising applying a gap-fill composition over a pattern comprising a plurality of gaps to be filled, resulting in the gap-fill composition being deposited in at least some of the gaps. The gap-fill composition comprises a polymer comprising a crosslinkable monomer and a second monomer different from the crosslinkable monomer. The gap-fill composition is crosslinked to form a gap-fill layer and one or more additional semiconductor processing steps are performed. The gap-fill layer is heated to its thermal decomposition temperature or higher, thereby removing at least some of the gap-fill layer.

The disclosure also provides a microelectronic structure comprising a pattern comprising a plurality of gaps and a gap-fill composition in at least some of the gaps. The gap-fill composition comprises a polymer comprising:
a first recurring monomer chosen from glycidyl methacrylate, glycidyl acrylate, (3,4-epoxycyclohexyl)methyl acrylate, or combinations thereof;
a second recurring monomer chosen from methyl methacrylate, benzyl methacrylate, methacrylic acid, cyclohexyl methacrylate, isopropyl methacrylate, phenyl methacrylate, or combinations thereof; and
a moiety at or near one end of the polymer, the moiety comprising

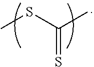

### BRIEF DESCRIPTION OF THE DRAWINGS

FIG. 1A-1C is a schematic depiction (not to scale) of a gap-fill process as described herein;

FIG. 2A-2B is a schematic depiction (not to scale) of a process for creating air gaps using the provided gap-fill compositions;

FIG. 3 provides graphs of the thermogravimetric analysis data described in Example 21 of the thermally decomposable polymers of Examples 1 and 3;

FIG. 4 depicts graphs of the isothermal thermogravimetric analysis data described in Example 21 of the thermally decomposable polymers of Examples 1 and 5;

FIG. 5 provides additional graphs of the isothermal thermogravimetric analysis data described in Example 21 of the thermally decomposable polymers of Examples 1, 5, and 7;

FIG. 6 provides scanning electron microscope (“SEM”) photographs of the gap-fill and thermal removal performance testing of the thermally decomposable polymer of Example 3 (see Example 22); and

FIG. 7 shows the XPS depth profiles of the gap-fill composition of Example 2 post-removal as compared to a blank control (see Example 23).

### DETAILED DESCRIPTION

The present disclosure is concerned with thermally-decomposable gap-fill compositions, methods of using those compositions, and the resulting structures. The disclosed compositions have improved gap-fill properties that are well-suited for multilayer photolithography applications.

### Gap-Fill Compositions

The gap-fill compositions provided herein generally comprise a polymer dispersed or dissolved in a solvent system, along with one or more optional ingredients, depending upon the embodiment.

### 1. Polymer

Suitable polymers comprise a crosslinkable monomer and a second monomer different from the crosslinkable monomer. The polymers can be purchased commercially or formed by any conventional polymerization method. The polymerization process broadly comprises polymerizing at least one crosslinkable monomer and a second monomer different from the crosslinkable monomer in a polymerization solution. One suitable polymerization method is Reversible Addition Fragmentation Chain Transfer (“RAFT”) polymerization, which broadly comprises polymerizing at least one crosslinkable monomer and a second monomer different from the crosslinkable monomer in a solution in the presence of an initiator and a chain transfer agent.

Regardless of the polymerization method, it is preferred that the crosslinkable monomer be selected such that self-crosslinking is possible so as to avoid the addition of a separate crosslinker. Preferred crosslinkable monomers include those containing an epoxy ring, such as those chosen from glycidyl methacrylate, glycidyl acrylate, (3,4-epoxycyclohexyl)methyl acrylate, or combinations thereof. The total crosslinkable monomer(s) in the polymerization solution is preferably present in an amount of about 1% to about 20% by weight, and more preferably about 1% to about 5%, by weight, based on the total weight of all monomers in the reaction solution taken as 100% by weight.

The second monomer may vary depending on a variety of factors such as desired T_{g}, final decomposition residuals desired, decomposition onset, degradation by-products, solubility, and other factors. In some embodiments, the T_{g} of a homopolymer of the second monomer is preferably at least about 80° C., and more preferably at least about 90° C., as determined by Differential Scanning Calorimetry as described in Example 24.

Preferred second monomers include those chosen from aliphatic methacrylates (preferably C₁-C₆; e.g., methyl methacrylate), benzyl methacrylate, methacrylic acid, cyclohexyl methacrylate, isopropyl methacrylate, phenyl methacrylate, or combinations thereof. The total second monomer(s) is preferably present in the polymerization solution in an amount of about 99% to about 80%, and more preferably about 99% to about 95%, based on the total weight of all monomers in the polymerization solution taken as 100% by weight.

In some embodiments, the molar ratio of crosslinkable monomer(s) to second monomer(s) is about 1:5 to about 1:100, preferably about 1:8 to about 1:70, more preferably about 1:10 to about 1:50, even more preferably about 1:10 to about 1:30, and most preferably about 1:10 to about 1:20.

In one or more embodiments, additional monomers (i.e., in addition to the crosslinkable monomer(s) and second monomer(s) as described above) can be included in the polymer. In such embodiments, it is preferred that the combined moles of crosslinkable monomer(s) and second monomer(s) as described above comprise at least about 50%, more preferably at least about 75%, and even more preferably at least about 90% of the total moles of all monomers in the polymer.

The polymerization reaction can be carried out in any suitable reaction solvent system, examples of which include one or more of propylene glycol monomethyl ether acetate (“PGMEA”), propylene glycol monomethyl ether (“PGME”), propylene glycol ethyl ether (“PGEE”), 3-methoxy methyl propionate (MMP), cyclopentanone, cyclohexanone, or mixtures thereof. The total amount of solvent in the polymerization reaction solution is preferably about 30% to about 80% by weight, more preferably about 40% to about 75% by weight, and even more preferably about 60% to about 70% by weight, based upon the total weight of the polymerization reaction solution taken as 100% by weight. The monomers are preferably present in the polymerization reaction solution in an amount of about 20% to about 70% by weight, more preferably about 30% to about 50% by weight, and even more preferably about 30% to about 35% by weight, based on the total weight of the polymerization reaction solution taken as 100% by weight.

Suitable radical initiators include one or more of 2,2′-azobis(2-methylpropionitrile) (“AIBN”), azobis(1-cyclohexanenitrile), Vazo™ 67 (Chemours Company FC, LLC), 4,4′-azobis(4-cyanovaleric acid) (“ACVA”), benzoyl peroxide, 1,1′-azobis(cyclohexanecarbonitrile) (“ACHN”), or combinations thereof. The total amount of radical initiator in the polymerization reaction solution is about 0.01% to about 0.5% by weight, preferably about 0.25% to about 0.25% by weight, and more preferably about 0.1% by weight, based upon the total weight of the polymerization reaction solution taken as 100% by weight.

Suitable chain transfer agents for embodiments made using RAFT polymerization include thiocarbonylthio compounds such as dithioesters, dithiobenzoates, dithiocarbamates, trithiocarbonates, and/or xanthates. Some preferred chain transfer agents for use herein include one or more chosen from 4-cyanopentanoic acid dithiobenzoate (“CPADB”), 4-cyano-4-(((dodecylthio)carbonothioyl)thio) pentanoic acid, 2-cyano-2-propyl dithiobenzoate, 4-((((2-carboxyethyl)thio)carbonothioyl)thio)-4-cyanopentanoic acid, 2-cyanobutan-2-yl dodecyl carbonotrithioate, methyl 4-cyano-4-(dodecylthiocarbonothioylthio)pentanoate, 2-cyano-5-hydroxypentan-2-yl dodecyl trithiocarbonate, 2-cyano-2-butylbenzodithiolate, 2-cyano-2-hexylbenzodithiolate, 2-cyano-3-methyl-2-butylbenzodithiolate, 2-cyano-2-pentylbenzodithiolate, 2-(2-cyanoprop-2-yl)-S-dodecyltrithiocarbonate, 2-phenyl-2-propyl benzodithioate, 4-cyano-4-(phenylcarbonothioylthio)pentanoic acid, 2-cyano-2-propyl dodecyl trithiocarbonate, 4-cyano-4-[(dodecylsulfanylthiocarbonyl)sulfanyl] pentanoic acid, or combinations thereof. The total amount of chain transfer agent in the polymerization reaction solution is about 1% to about 10% by weight, preferably about 1% to about 3% by weight, and more preferably about 2% by weight, based upon the total weight of the polymerization reaction solution by weight.

In some embodiments, the molar ratio of radical initiator to chain transfer agents is about 1:3 to about 1:20, preferably about 1:5 to about 1:15, more preferably about 1:5 to about 1:10, and even more preferably about 1:10.

The polymerization reaction is preferably carried out under nitrogen with stirring at a temperature of about 65° C. to about 90° C., and more preferably about 70° C. to about 75° C., for about 16 hours to about 30 hours, and more preferably about 22 hours to about 26 hours.

The resulting polymer preferably has a weight average molecular weight (as determined by GC) of about 2,000 g/mol to about 10,000 g/mol, more preferably about 4,000 g/mol to about 8,000 g/mol, and even more preferably about 5,000 g/mol to about 7,000 g/mol.

Exemplary polymers include:

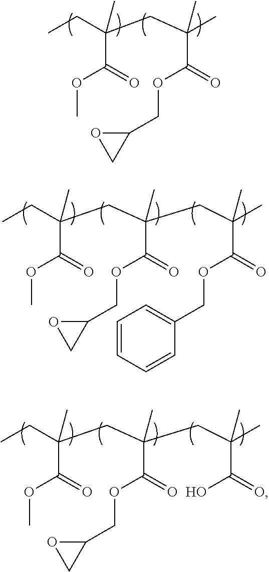

where the monomers are randomly distributed within the polymer.

The choice of initiator will determine the end group of the polymer chain for polymers made using RAFT polymerization. Preferred polymers will have the following moiety at or near one end of the polymer (preferably as part of an end group):

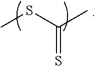

In preferred embodiments, this moiety is not present at any other location in the polymer. Examples of preferred end groups include:

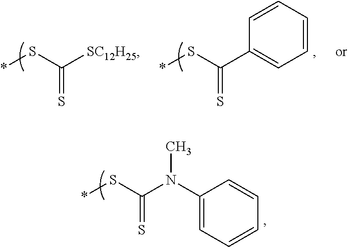

where “*” represents the point of attachment to the polymer.

In some embodiments, the polymer comprises less than about 10% by weight, preferably less than about 8% by weight, and more preferably less than about 5% by weight of the end group.

Two preferred polymers have the following (random) monomer and end group structures:

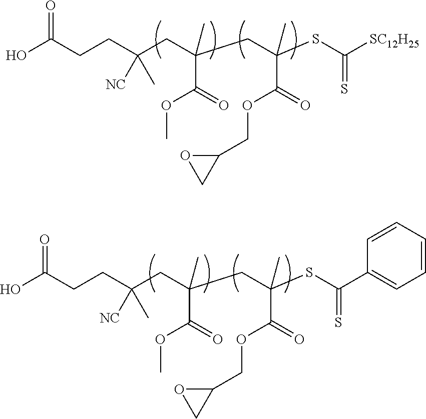

In some embodiments, the polymer consists essentially of, or even consists of, the crosslinkable monomer(s) and second monomer(s) as described above. In other embodiments, the polymer consists essentially of, or even consists of at least one of glycidyl methacrylate, glycidyl acrylate, and/or (3,4-epoxycyclohexyl)methyl acrylate; and at least one of methyl methacrylate, benzyl methacrylate, methacrylic acid, cyclohexyl methacrylate, isopropyl methacrylate, and/or phenyl methacrylate.

In some embodiments, the polymer consists essentially of, or even consists of, the crosslinkable monomer(s), second monomer(s), and an end group from the RAFT polymerization process (i.e., an end group that is a derived from the initiator used in the RAFT process, such as the moieties described above). In other embodiments, the polymer consists essentially of, or even consists of: at least one of glycidyl methacrylate, glycidyl acrylate, and/or (3,4-epoxycyclohexyl)methyl acrylate; at least one of methyl methacrylate, benzyl methacrylate, methacrylic acid, cyclohexyl methacrylate, isopropyl methacrylate, and/or phenyl methacrylate; and an end group from the RAFT polymerization process.

The resulting polymer preferably has a T_{g} of about 30° C. to about 90° C., more preferably about 40° C. to about 70° C., and even more preferably about 50° C. to about 60° C. Additionally or alternatively, the resulting polymer preferably has a T_{d} of about 200° C. to about 450° C., more preferably about 275° C. to about 350° C., and even more preferably about 300° C. to about 330° C. As used herein, T_{d} is determined by thermogravimetric analysis, as described in Example 21.

### 2. Gap-Fill Composition Formulations

The inventive compositions comprise a polymer as described above dispersed or dissolved in a solvent system.

The polymer will preferably be present at a level of about 0.5% to about 10% by weight, more preferably about 1% to about 5% by weight, even more preferably about 1.5% to about 3.5% by weight, and most preferably about 2% to about 2.5% by weight, based upon the total weight of the gap-fill composition taken as 100% by weight. Additionally or alternatively, the polymer is preferably present in the about 90% to about 100% by weight, more preferably about 95% to about 99.9% by weight, and even more preferably about 98% to about 99.8% by weight, based upon the total weight of all solids present in the gap-fill composition taken as 100% by weight.

In some embodiments, a crosslinking catalyst may be included in the gap-fill composition. Suitable catalysts include those chosen from thermal acid generators (TAGs, such as TAG2689 from King Industries and TAG2690 from King Industries), benzyltriethylammonium chloride (“BTEAC”), ethyltriphenylphosphonium bromide, tetrabutylphosphonium bromide, or combinations thereof. The crosslinking catalyst is preferably present in the particular composition at levels of about 0.1% to about 5% by weight, more preferably about 0.5% to about 2% by weight, and even more preferably about 1% by weight, based upon the total weight of the polymer taken as 100% by weight.

In some embodiments, a surfactant may be included in the gap-fill composition to improve coating quality. Nonionic surfactants such as R30N (DIC Corporation, Japan) and FS3100 (The Chemours Company FC, LLC. USA) are preferred. The surfactant is preferably present in the particular gap-fill composition at a level of about 0.1% to about 1% by weight, and more preferably about 0.2% to about 0.5% by weight, based upon the total weight of the polymer taken as 100% by weight.

The above ingredients are mixed in the solvent system to form the particular gap-fill composition. Preferred solvent systems include one or more solvents chosen from PGMEA, PGME, cyclohexanone, cyclopentanone, PGEE, ethyl lactate, gamma-butyrolactone (GBL), or mixtures thereof. The solvent system is preferably utilized at a level of about 90% to about 99% by weight, more preferably about 94% to about 98% by weight, and even more preferably about 95% to about 97% by weight, based upon the total weight of the gap-fill composition taken as 100% by weight. The material is preferably filtered before use, such as with a 0.1-μm or 0.2-μm PTFE filter, or a sub-1-nm Nylon filter.

In some embodiments, the gap-fill composition does not include water. That is, the composition will comprise less than about 3% by weight, preferably less than about 1.5% by weight, and more preferably about 0% by weight water.

In some embodiments, the gap-fill composition may contain optional ingredients, such as those chosen from crosslinking catalysts, surfactants, other polymers, additives, or mixtures thereof.

In one or more embodiments, the composition is essentially free of crosslinking agents. That is, the gap-fill composition will comprise less than about 3% by weight, preferably less than about 1.5% by weight, and more preferably about 0% by weight crosslinking agents.

In another embodiment, the gap-fill composition consists essentially of, or even consists of, the polymer dispersed or dissolved in the solvent system. In a further embodiment, the gap-fill composition consists essentially of, or even consists of, the polymer and crosslinking catalyst dispersed or dissolved in the solvent system. In yet a further embodiment, the composition consists essentially of, or even consists of, the polymer, crosslinking catalyst, and surfactant dispersed or dissolved in the solvent system.

### Methods of Forming Gap-Fill Layers

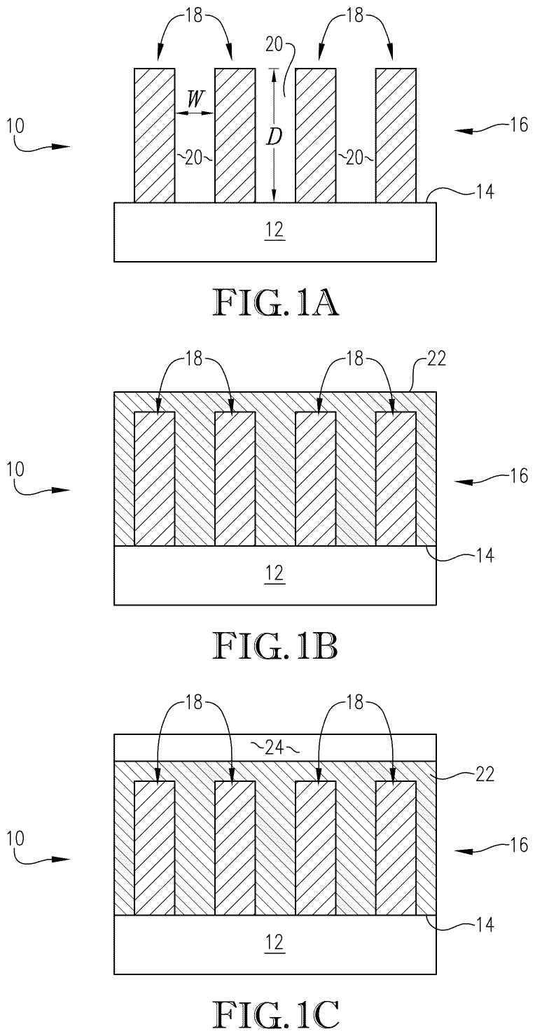

Referring to FIG. 1A, a microelectronic structure 10 is shown. Structure 10 comprises a substrate 12 having a surface 14. While any microelectronic substrate can be utilized, a semiconductor substrate is a preferred substrate 12. Examples of suitable substrates 12 include those formed of one or more of the following materials: silicon, SiGe, SiO₂, Si₃N₄, SiON, aluminum, tungsten, tungsten silicide, gallium arsenide, germanium, tantalum, tantalum nitride, Ti₃N₄, hafnium, HfO₂, ruthenium, indium phosphide, or glass. One or more optional intermediate layers (not shown) may be formed on substrate surface 14. One such intermediate layer, for example, comprises a TiN layer.

In the embodiment illustrated, structure 10 further comprises a topographical pattern 16 (e.g., lithographically formed) on substrate surface 14 (or on any intermediate layers that might be present on substrate surface 14). However, in some embodiments (not shown), topographical pattern 16 may be formed in upper surface 14 of substrate 12. Topographical pattern 16 includes topographic features 18, which define a plurality of gaps 20. Examples of topographic features 18 include lines, gates, raised features, and/or pillars.

Gaps 20 can be holes (e.g., via and/or contact holes), trenches, spacing between lines, pores in a porous material, and/or any other spacing or void. Gaps 20 have respective widths “W” and depths “D,” as shown in FIG. 1A. The respective widths “W” of gaps 20 can be the same or different widths and are typically quite small, e.g., less than about 100 nm, preferably less than about 75 nm, more preferably less than about 50 nm, even more preferably less than about 25 nm, and most preferably less than about 10 nm. The respective depths “D” of gaps 20 can be the same or different and are comparatively deep, such as about 10 nm to about 10 μm, preferably about 100 nm to about 5 μm, more preferably about 200 nm to about 1,000 nm, and even more preferably about 200 nm to about 500 nm.

The gaps 20 have a high aspect ratio, where “aspect ratio” is defined as D/W. Aspect ratios used in the process described herein will generally be about 2 or greater, preferably about 3 or greater, more preferably about 4 or greater, and even more preferably about 5 or greater. Typical ranges of aspect ratios will be about 2 to about 100, about 3 to about 50, about 4 to about 25, and even more preferably about 5 to about 20.

As shown in FIG. 1B, a gap-fill composition as described herein is applied to topographical pattern 16 so that at least some of the gap-fill composition is deposited in at least some of the gaps 20 in the pattern. In some embodiments, there might be one or more intermediate layers (not shown) first applied to topographical pattern 16, and the gap-fill composition would be applied to the uppermost (i.e., last) such intermediate layer. Examples of such intermediate layers include one or more of high-carbon layers, silicon hardmasks, metal hardmasks, metals, or dielectrics.

Regardless of whether an intermediate layer was first applied to topographical pattern 16, the gap-fill composition can be applied by any known application method, with one preferred method being spin coating at speeds of about 1,000 rpm to about 4,000 rpm, preferably about 1,000 rpm to about 2,500 rpm, and more preferably about 1,500 rpm. Spin coating times are typically about 30 seconds to about 180 seconds, preferably about 30 seconds to 60 seconds, and more preferably about 60 seconds. Preferably, the gap-fill composition has good spin bowl compatibility, meaning that it will not react or form a precipitate with common photoresist solvents such as PGME, PGMEA, ethyl lactate, cyclohexanone, or combinations thereof.

After the gap-fill composition is applied, it is preferably heated to a temperature that is at least the crosslinking temperature (“T_{c}”) of the gap-fill composition but lower than the thermal decomposition temperature (“T_{d}”) of the gap-fill composition. Gap-fill compositions as described herein typically have a crosslinking temperature of about 160° C. to about 220° C., and preferably about 170° C. to about 205° C., and these are also preferred heating temperatures for crosslinking.

In some embodiments, the gap-fill composition is heated to a temperature that is about 20° C. or more below T_{d}, preferably about 40° C. or more below T_{d}, and more preferably about 60° C. or more below the T_{d}. This heating is typically carried out for about 30 seconds to about 120 seconds, and preferably about 60 seconds to about 90 seconds, resulting in evaporation of solvents and crosslinking of the gap-fill composition to form gap-fill layer 22.

The average thickness of the gap-fill layer 22 after baking is preferably about 50 nm to about 3 μm, more preferably about 100 nm to about 300 nm, and even more preferably about 150 nm to about 200 nm. The average thickness is determined by taking the average of thickness measurements at five different locations of the gap-fill layer 22, with those thickness measurements being obtained using ellipsometry. In some embodiments, the foregoing thicknesses are achieved in the gaps 20. In this or other embodiments, the foregoing thicknesses are achieved over the “tallest” or highest (relative to surface 14) topographic features 18.

Gap-fill layer target thickness is first determined by coating films of various thicknesses, typically starting at a thickness close to the topography depth, onto topography substrates. Films are then baked and then percent fill of the desired topography is measured via cross-sectional SEM examination. Depending on level of overfill (overburden) or underfill, film thickness can be adjusted either higher or lower. In most cases, the thickness that gives at least about 100% fill of the topography is desired, but overburden or underfill may be desired in some applications. Preferably, the gap-fill layer fills the gaps 20 without voids in the layer, as measured by a cross-sectional SEM.

In some embodiments, gap-fill layer 22 is resistant to solvent stripping when a strip test is performed. As used herein, a “strip test” comprises coating the gap-fill composition onto a flat substrate (i.e., a substrate without topography) and baking at a temperature of about 200° C. for about 60 seconds. The thickness of the layer is measured via ellipsometry. PGMEA is puddled on the coated substrate for about 20 seconds and spun dry. The thickness of the layer is then measured again to determine any thickness loss. Preferably, there is less than about 5% thickness loss, more preferably less than about 1% film thickness loss, and even more preferably about 0% thickness loss.

Next, further processing can be performed on the structure 10, with that processing being selected by the user, depending on the particular application. For example, one or more additional layers 24 (see FIG. 1C) may be applied to gap-fill layer 22. The one or more additional layers 24 can be formed by any known application method, such as chemical vapor deposition (“CVD”), plasma-enhanced chemical vapor deposition (“PECVD”), atomic layer deposition (“ALD”), or spin coating.

Typically, “further processing” will include forming a photoresist layer (not shown) on the gap-fill layer 22. Alternatively, a photoresist layer can be formed on any intermediate layer(s) (e.g., spin-on carbon layer, hardmask, dielectric, metal) that might have first been formed on gap-fill layer 22). The photoresist layer can be formed by any conventional method, with one preferred method being spin coating the photoresist composition at speeds of about 350 rpm to about 4,000 rpm (preferably about 1,000 rpm to about 2,500 rpm) for a time period of about 10 seconds to about 60 seconds (preferably about 10 seconds to about 30 seconds). The photoresist layer is then optionally post-application baked (“PAB”) at a temperature of at least about 70° C., preferably about 80° C. to about 150° C., and more preferably about 100° C. to about 150° C., for time periods of about 30 seconds to about 120 seconds. The average thickness (determined as described previously) of the photoresist layer after baking will typically be about 5 nm to about 120 nm, preferably about 10 nm to about 50 nm, and more preferably about 20 nm to about 40 nm.

The photoresist layer is subsequently patterned by exposure to radiation for a dose of about 10 mJ/cm² to about 200 mJ/cm², preferably about 15 mJ/cm² to about 100 mJ/cm², and more preferably about 20 mJ/cm² to about 50 mJ/cm². More specifically, the photoresist layer is exposed using a mask positioned above the surface of the photoresist layer. The mask has areas designed to permit the radiation to reflect from or pass through the mask and contact the surface of the photoresist layer. The remaining portions of the mask are designed to absorb the light to prevent the radiation from contacting the surface of the photoresist layer in certain areas. Those skilled in the art will readily understand that the arrangement of reflecting and absorbing portions is designed based upon a desired pattern to be formed in the photoresist layer and ultimately in the substrate or any intermediate layers.

After exposure, the photoresist layer is preferably subjected to a post-exposure bake (“PEB”) at a temperature of less than about 180° C., preferably about 60° C. to about 140° C., and more preferably about 80° C. to about 130° C., for a time period of about 30 seconds to about 120 seconds, and preferably about 30 seconds to about 90 seconds.

The photoresist layer is then contacted with a developer to form the pattern. Depending upon whether the photoresist used is positive-working or negative-working, the developer will either remove the exposed portions of the photoresist layer or remove the unexposed portions of the photoresist layer to form the pattern. The pattern is typically transferred through the various layers, possibly even through the gap-fill layer 22 and into the substrate 12, depending on the embodiment and the particular structure being formed. This pattern transfer can take place via plasma etching (e.g., CF₄ etchant, O₂ etchant) or a wet etching or developing process.

Other “further processing” includes one or more of polishing, chemical-mechanical planarization, ion implantation, and/or metallization.

Once the further processing is complete, the substrate 12 is subjected to a bake step to thermally decompose the gap-fill layer 22. In this step, the gap-fill layer 22 is heated to a temperature that is approximately equal to, but preferably greater than, the T_{d} of gap-fill layer 22. In some embodiments, this temperature is at least about 25° C. greater than the T_{d} of gap-fill layer 22, and preferably at least about 10° C. greater than the T_{d} of gap-fill layer 22. Preferred heating times are about 120 seconds to about 60 minutes, and preferably about 900 seconds to about 30 minutes.

In some embodiments, preferred bake temperatures are about 300° C. or greater, preferably about 300° C. to about 450° C., and more preferably about 350° C. to about 400° C., for about 120 seconds to about 60 minutes, and preferably about 15 minutes to about 30 minutes.

In some embodiments, the bake step is performed in an inert atmosphere. After the bake step is complete, preferably at least about 95% of the gap-fill layer 22 is removed from the substrate surface, more preferably at least about 99%, and even more preferably at least about 99.9% (hereinafter referred to as “% removal”). In cases where the gap-fill material is not completely removed, additional cleaning steps may be used to remove any residual material.

The % removal of gap-fill layer 22 is determined by coating and baking the gap-fill composition as described above on a flat substrate (i.e., one having no topography), and measuring the average thickness of the crosslinked gap-fill layer, such as via ellipsometry. The layer is then baked at a temperature above the T_{d} (e.g., about 400° C.) for about 30 minutes, and the average thickness of the gap-fill layer is measured again. Residual film may also be determined using analytical techniques such as XPS.

Gap-fill testing can be performed by coating the material on suitable substrates and viewing a cross-section of the features. Typical substrates for checking gap-fill performance are made via formation of about 500-nm deep (i.e., “D” as defined above) silicon oxide trenches patterned to about 180 nm feature width at a density of about 1:1. The feature size is reduced by deposition of about 80 nm of silicon nitride via a CVD process. The resulting features range from about 20 nm to about 10 nm wide (“W”) trenches. The gap-fill composition to be tested is spin-coated and baked to crosslink according to the parameters given. Substrates are examined via SEM for adequate gap-filling without voids or delamination and with minimal residues post-decomposition. The material should not have voiding, bubbles, or delamination from the side walls after the standard spin and bake process.

Advantageously, the disclosed gap-fill compositions are able to completely fill the gaps 20 when “D” (see FIG. 1A) is about 10 μm or less and “W” is about 500 nm or less, preferably when “D” is about 500 nm or less and “W” is about 100 nm or less, and more preferably when “D” is about 200 nm or less and “W” is about 50 nm or less.

A second set of substrates can also be prepared for clean-out performance testing by baking at the crosslinking temperature and then baking again at the thermal decomposition temperature, as described previously. After the removal process, the substrates are visually examined via SEM to determine the extent of residues present either on the top surfaces or in the bottoms of the trenches. In preferred embodiments, there is no residue on the top surfaces or in the bottoms of the trenches upon visual inspection via SEM. However, this is not strictly required for applications in which there may be tolerance for some residues.

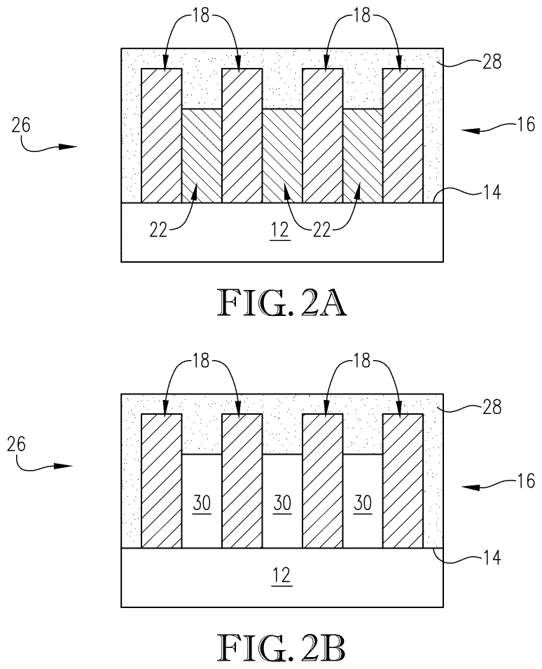

FIG. 2 illustrates an alternative process using the gap-fill compositions described herein, with like numbering referring to like parts. Referring to FIG. 2A, structure 26 is depicted, with a substrate 12 also having a topographical pattern 16 in or on substrate surface 14. In this embodiment, a gap-fill layer 22 partially fills at least some of the gaps between the topographic features 18 and a support material or layer 28 is formed on gap-fill layer 22 and topographic features 18. Layer 28 can be formed as described above with respect to the photoresist or other layers and can be any type of layer desired by the end user for the particular process. Gap-fill layer 22 is then subjected to the previously described thermal decomposition process to remove gap-fill layer 22, thus forming air gaps 30 under the support layer 28 where gap-fill layer 22 used to be disposed (FIG. 2B). Thus, the support layer 28 serves as a cap over the air gaps 30. Further processing can be carried out on layer 28, as desired for the particular application. Advantageously, this process provides a method for creating air gaps around features having a high aspect ratio, which can be desirable for certain types of further processing, while avoiding pattern collapse.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Decomposable Polymer 1

In this Example, 95.11 grams of methyl methacrylate (TCI chemicals, Portland, OR), 7.11 grams of glycidyl methacrylate (Monomer Polymer and Dajac Labs, Ambler, PA), 7.76 grams of 4-cyano-4-(((dodecylthio)carbonothioyl)thio) pentanoic acid (Boron Molecular, Raleigh, NC), 0.316 gram of 2,2′-azobis(2-methylpropionitrile) (AIBN) (Charkit, Norwalk, CT), and 204.44 grams of PGMEA (Fujifilm Ultra Pure Solutions, Inc., Carrollton, TX) were added to a round bottom flask and sparged with N₂ for 10 minutes. The reaction was held at 70° C. under nitrogen with magnetic stirring for 24 hours.

### Example 2

### Gap-Fill Composition Using Decomposable Polymer 1

A gap-fill composition was prepared by adding 4.9595 grams of the mother liquor from Example 1, 0.0141 gram of TAG2689 (King Industries, Norwalk, CT), 70.0264 grams of PGMEA, and 25.0 grams of PGME (Fujifilm Ultra Pure Solutions, Inc., Carrollton, TX) to a 250-mL Nalgene bottle, followed by mixing for 24 hours. The resulting solution was filtered with a 0.1-μm PTFE endpoint filter.

### Example 3

### Decomposable Polymer 2

In this Example, 9.51 grams of methyl methacrylate, 0.71 gram of glycidyl methacrylate, 0.46 gram of 4-cyanopentanoic acid dithiobenzoate (CPADB) (Strem, Newburyport, MA), 0.027 gram of AIBN, and 10.22 grams of PGMEA were added to a 100-mL round bottom flask and sparged with N₂ for 10 minutes. The flask was then placed in an oil bath at 75° C. for 24 hours before being cooled to room temperature, diluted with acetone, and precipitated into ˜600 mL hexanes. The resulting solid was collected by suction and dried at 40° C. under vacuum overnight.

### Example 4

### Gap-Fill Composition Using Decomposable Polymer 2

A gap-fill composition was prepared by adding 1.4851 grams of the polymer from Example 3, 0.0149 gram of TAG2689, 73.5 grams of PGMEA, and 25.0 grams of PGME to a 250-mL Nalgene bottle, followed by mixing for 24 hours. The resulting solution was filtered with a 0.1-μm PTFE endpoint filter.

### Example 5

### Decomposable Polymer 3

A thermally decomposable polymer was prepared by adding 3.60 grams of methyl methacrylate, 6.34 grams of benzyl methacrylate (TCI chemicals, Portland, OR), 1.14 grams of glycidyl methacrylate, 0.538 gram of 4-cyano-4-(((dodecylthio)carbonothioyl)thio) pentanoic acid, 0.022 gram of AIBN, and 22.17 grams of PGMEA to a 100-mL round bottom flask, followed by sparging with nitrogen for 10 minutes before being heated at 70° C. for 24 hours. The reaction was then diluted with acetone and precipitated in ˜400 mL hexanes. The solid was collected by suction and dried under vacuum at 40° C. overnight.

### Example 6

### Gap-Fill Composition Using Decomposable Polymer 3

A gap-fill composition was prepared by adding 1.4851 grams of the polymer from Example 5, 0.0149 gram of TAG2689, 73.8750 grams of PGMEA, and 24.6250 grams of PGME to a 250-mL Nalgene bottle, followed by mixing for 24 hours. The resulting solution was filtered with a 0.1-μm PTFE endpoint filter.

### Example 7

### Decomposable Polymer 4

In this Example, 5.61 grams of methyl methacrylate, 1.38 grams of methacrylic acid (TCI chemicals, Portland, OR), 1.14 grams of glycidyl methacrylate, 0.538 gram of 4-cyano-4-(((dodecylthio)carbonothioyl)thio) pentanoic acid, 0.022 gram of AIBN, and 16.24 grams of PGMEA were added to a 100-mL round bottom flask and sparged with nitrogen for 10 minutes before being heated at 70° C. for 24 hours. The reaction was then diluted with acetone and precipitated in ˜400 mL hexanes. The solid was collected by suction and dried under vacuum at 40° C. overnight.

### Example 8

### Gap-Fill Composition Using Decomposable Polymer 4

A gap-fill composition was prepared by adding 1.4851 grams of the polymer from Example 7, 0.0149 gram of TAG2689, 73.8750 grams of PGMEA, and 24.6250 grams of PGME to a 250-mL Nalgene bottle, followed by mixing for 24 hours. The resulting solution was filtered with a 0.1-μm PTFE endpoint filter.

### Example 9

### Decomposable Polymer 5

A thermally decomposable polymer was prepared by adding 9.9119 grams of methyl methacrylate, 0.1422 grams of glycidyl methacrylate, 0.6728 gram of 4-cyano-4-(((dodecylthio)carbonothioyl)thio) pentanoic acid, 0.02737 gram of 2,2′-azobis(2-methylpropionitrile), and 20.11 grams of PGMEA to a round bottom flask, followed by sparging with N₂ for 10 minutes. The reaction was held at 70° C. under nitrogen with magnetic stirring for 24 hours.

### Example 10

### Gap-Fill Composition Using Decomposable Polymer 5

In this Example, 4.9595 grams of the mother liquor from Example 9, 0.0141 gram of TAG2689, 70.0264 grams of PGMEA, and 25.0 grams of PGME were added to a 250-mL Nalgene bottle and mixed for 24 hours. The resulting solution was filtered with a 0.1-μm PTFE endpoint filter.

### Example 11

### Decomposable Polymer 6

A polymer was prepared by adding 9.8118 grams of methyl methacrylate, 0.2843 gram of glycidyl methacrylate, 0.6728 gram of 4-cyano-4-(((dodecylthio)carbonothioyl)thio) pentanoic acid, 0.0274 gram of 2,2′-azobis(2-methylpropionitrile), and 20.1921 grams of PGMEA to a round bottom flask, followed by sparging with N₂ for 10 minutes. The reaction was held at 70° C. under nitrogen with magnetic stirring for 24 hours.

### Example 12

### Gap-Fill Composition Using Decomposable Polymer 6

A gap-fill composition was prepared by adding 4.9595 grams of the mother liquor from Example 11, 0.0141 gram of TAG2689, 70.0264 grams of PGMEA, and 25.0 grams of PGME to a 250-mL Nalgene bottle, followed by mixing for 24 hours. The resulting solution was filtered with a 0.1-μm PTFE endpoint filter.

### Example 13

### Decomposable Polymer 7

In this Example, 9.7116 grams of methyl methacrylate, 0.4265 gram of glycidyl methacrylate, 0.6728 gram of 4-cyano-4-(((dodecylthio)carbonothioyl)thio) pentanoic acid, 0.0274 gram of 2,2′-azobis(2-methylpropionitrile), and 20.3602 grams of PGMEA were added to a round bottom flask and sparged with N₂ for 10 minutes. The reaction was held at 70° C. under nitrogen with magnetic stirring for 24 hours.

### Example 14

### Gap-Fill Composition Using Decomposable Polymer 7

A gap-fill composition was prepared by adding 4.9595 grams of the mother liquor from Example 13, 0.0141 gram of TAG2689, 70.0264 grams of PGMEA, and 25.0 grams of PGME to a 250-mL Nalgene bottle, followed by mixing for 24 hours. The resulting solution was filtered with a 0.1-μm PTFE endpoint filter.

### Example 15

### Decomposable Polymer 8

In this Example, 9.6115 grams of methyl methacrylate, 0.5686 gram of glycidyl methacrylate, 0.6728 gram of 4-cyano-4-(((dodecylthio)carbonothioyl)thio) pentanoic acid, 0.0274 gram of 2,2′-azobis(2-methylpropionitrile), and 20.3602 grams of PGMEA were added to a round bottom flask and sparged with N₂ for 10 minutes. The reaction was held at 70° C. under nitrogen with magnetic stirring for 24 hours.

### Example 16

### Gap-Fill Composition Using Decomposable Polymer 8

A gap-fill composition was prepared by adding 4.9595 grams of the mother liquor from Example 15, 0.0141 gram of TAG2689, 70.0264 grams of PGMEA, and 25.0 grams of PGME to a 250-mL Nalgene bottle, followed by mixing for 24 hours. The resulting solution was filtered with a 0.1-μm PTFE endpoint filter.

### Example 17

### Decomposable Polymer 9

A thermally decomposable polymer was prepared by adding 9.0108 grams of methyl methacrylate, 1.4215 gram of glycidyl methacrylate, 0.6728 gram of 4-cyano-4-(((dodecylthio)carbonothioyl)thio) pentanoic acid, 0.0274 gram of 2,2′-azobis(2-methylpropionitrile), and 20.8646 grams of PGMEA to a round bottom flask, followed by sparging with N₂ for 10 minutes. The reaction was held at 70° C. under nitrogen with magnetic stirring for 24 hours.

### Example 18

### Gap-Fill Composition Using Decomposable Polymer 9

In this Example, 4.9595 grams of the mother liquor from Example 17, 0.0141 gram of TAG2689, 70.0264 grams of PGMEA, and 25.0 grams of PGME were added to a 250-mL Nalgene bottle and mixed for 24 hours. The resulting solution was filtered with a 0.1-μm PTFE endpoint filter.

### Example 19

### Comparative Polymer

A thermally decomposable polymer was prepared by adding 7.609 grams of methyl methacrylate, 0.5686 grams of glycidyl methacrylate, 0.197 gram of 2,2′-azobis(2-methylpropionitrile), and 24.53 grams of PGMEA to a round bottom flask, followed by sparging with N₂ for 10 minutes. The reaction was held at 75° C. under nitrogen with magnetic stirring for 24 hours.

### Example 20

### Comparative Gap-Fill Composition

In this Example, 4.9595 grams of the mother liquor from Example 9, 0.0141 gram of TAG2689, 70.0264 grams of PGMEA, and 25.0 grams of PGME were added to a 250-mL Nalgene bottle and mixed for 24 hours. The resulting solution was filtered with a 0.1-μm PTFE endpoint filter.

### Example 21

### Thermogravimetric Analysis of Decomposable Polymers 1-4

TGA testing of the polymers from Examples 1 and 3 was done by precipitation of the polymer mother liquor via dilution with acetone, precipitation into hexanes, collection of solids via suction, and then drying under vacuum at 40° C. overnight. The collected polymer solids were then analyzed using TA Instruments Q500 thermogravimetric analyzer (platinum pans, N₂ or air, various ramp and hold conditions).

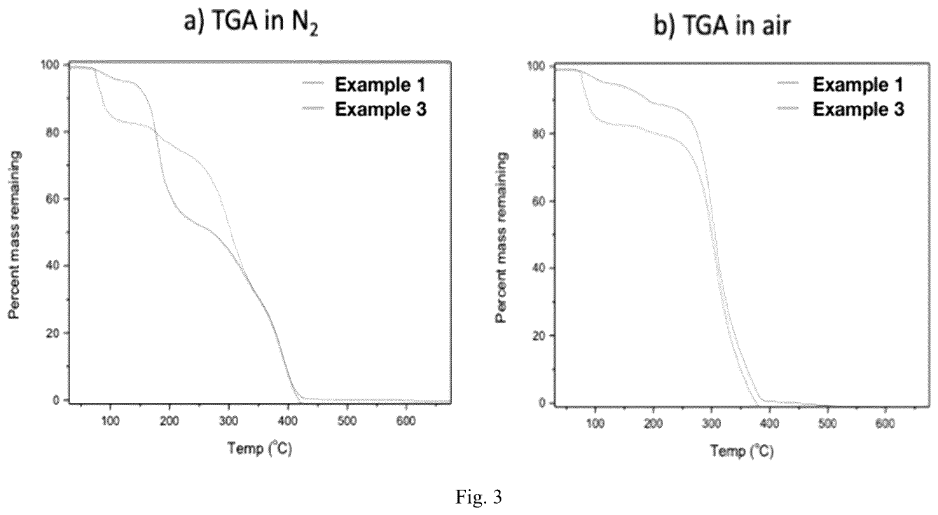

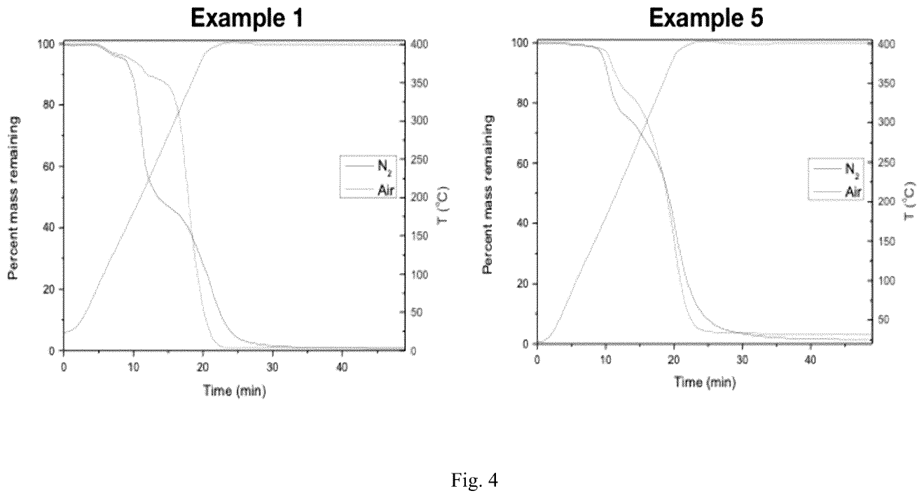

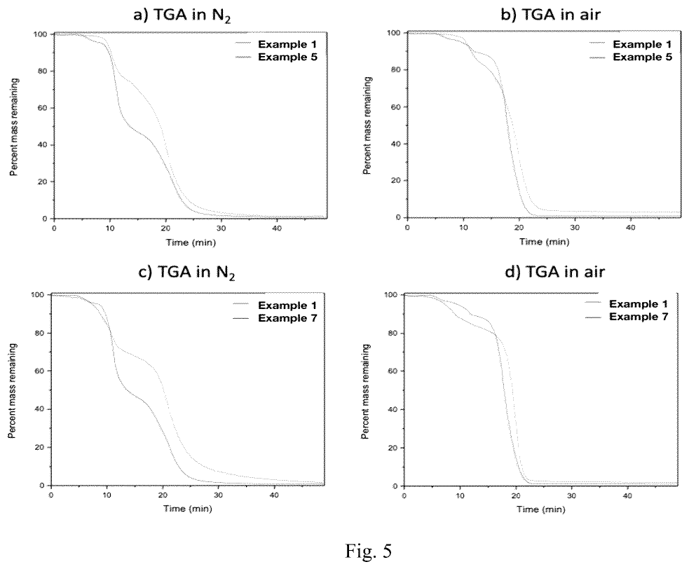

FIG. 3 shows the TGA for the decomposable polymers from Examples 1 and 3 using a 10° C./minute ramp from room temperature to 700° C. FIG. 4 shows the isothermal TGA data for Examples 1 and 5 using a 10° C./minute ramp to 400° C. and then holding for 30 minutes. FIG. 5 shows the isothermal TGA data for Examples 1, 5, and 7 in both air and nitrogen using a 10° C./minute ramp to 400° C. and holding for 30 minutes. As shown in FIGS. 3-5, all of these materials were nearly completely removed in both oxygen-containing and nitrogen atmospheres.

### Example 22

### Gap-Fill Performance Testing of Decomposable Polymer 1

The gap-fill composition from Example 2, which included decomposable polymer 1, was spin coated onto topography chips (AMTi Japan, silicon nitride-coated silicon oxide substrates, 10-nm wide by 500-nm deep) at 1,500 rpm for 60 seconds and then baked at 205° C. for 60 seconds. One chip was baked again at 400° C. under N₂ for 30 minutes for thermal removal of the gap-fill layer. Both chips were submitted for cross-section SEM (Hitachi Ethos NX5000). Chips were cross-sectioned, sputtered with a thin layer of platinum, and then imaged at 200K magnification, acceleration voltage 3.0 kV, 5.0 pA current, FOV at 1.5 um using upper detector, and viewing angle at 1.5 degrees.

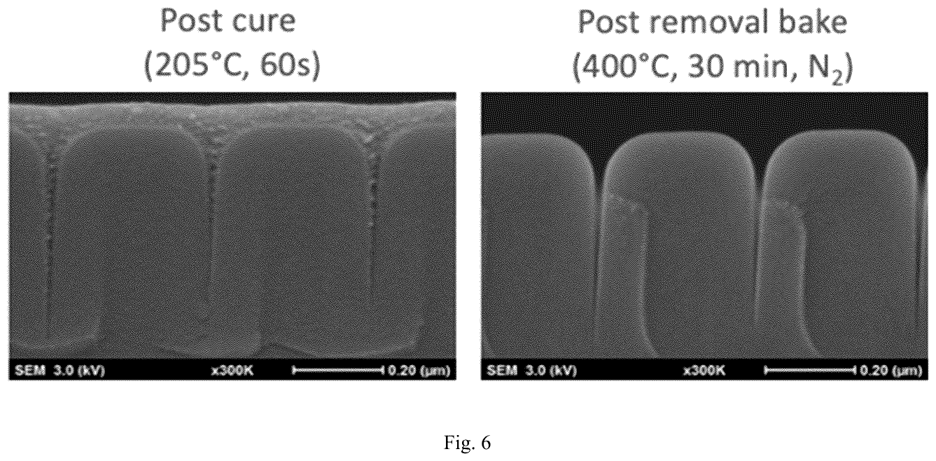

As shown in FIG. 6, gap-fill performance and thermal removal of the material from Example 2 on sub-20-nm features was exceptional, with no residues detected after the complete removal process.

### Example 23

### XPS Removal Testing of Gap-Fill Composition of Example 2

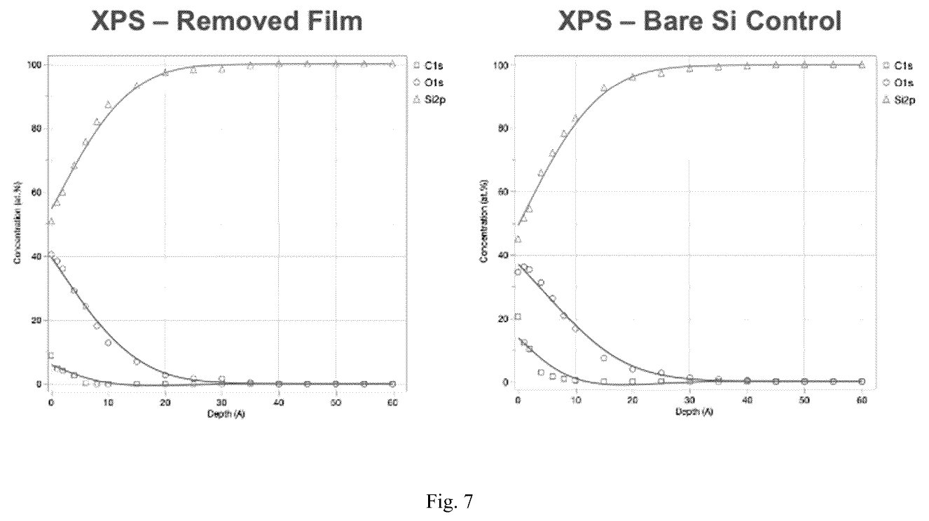

The gap-fill composition from Example 2 was coated onto a bare Si wafer at 1,500 rpm, baked at 180° C. for 1 minute, then baked under N₂ at 400° C. for 30 minutes on a hot plate to remove the film. Testing was performed on a PHI Quantum 2000 with the following parameters: monochromated Alka 1486.6 eV; acceptance angle +23°; take-off angle 45°; analysis area 600 mm; charge correction CIs 284.8 eV; ion gun conditions 1) Ar+, 1 keV, 2 mm×2 mm raster, 2) Ar+, 0.5 keV, 2 mm×2 mm raster; Sputter rates 1) 31 Å/min, 2) 10 Å/min; and Zalar rotation off. FIG. 7 shows the XPS depth profile of the wafer after the 400° C. bake compared to the XPS depth profile of a blank silicon control wafer. This testing confirms minimal residue is left behind after the thermal removal process.

### Example 24

### Glass Transition Temperatures of Various Polymers

To determine the bulk T_{g} of the polymers, the polymers of Examples 1, 9, 11, 13, 15, and 17 were precipitated in hexanes, and the solids were collected by filtration followed by drying under vacuum to remove volatiles. The powders were then run in a differential scanning calorimeter (“DSC”) using the following procedure: heat to 180° C., cool to 20° C., and heat to 180° C. using a heating/cooling rate of 10° C./min. The T_{g} was extracted from the transition in the second heating curve.

To determine the T_{g} after crosslinking, the polymers from Examples 1, 9, 11, 13, 15, and 17 were coated onto a bare Si wafer at 1,000 rpm and baked at 205° C. for 1 minute. The films were then scraped off the wafer and run in a DSC using the same procedure described in the preceding paragraph: heat to 180° C., cool to 20° C., and heat to 180° C. using a heating/cooling rate of 10° C./min. The T_{g} was extracted from the transition in the second heating curve.

Table 1 shows the T_{g} of each of the polymer examples before and after crosslinking.

TABLE 1
Glass transition temperature (T_{g}) of polymers

| | | T_{g} |
|---|---|---|
| | T_{g} | after |
| | before | XL or |
| Polymer | XL* | 205° C. bake |
| Example 1 | 56° C. | 110° C. |
| Example 9 | 52° C. | 80° C. |
| Example 11 | 54° C. | 81° C. |
| Example 13 | 54° C. | 90° C. |
| Example 15 | 54° C. | 95° C. |
| Example 17 | 48° C. | 122° C. |
| Example 19 | 83° C. | 112° C. |

*XL = crosslinking

1. A gap-fill method comprising:
applying a gap-fill composition over a pattern comprising a plurality of gaps to be filled, wherein:
said gap-fill composition comprises a polymer comprising:
a crosslinkable monomer; and
a second monomer different from said crosslinkable monomer; and
said applying results in said gap-fill composition being deposited in at least some of said gaps;
crosslinking said gap-fill composition to form a gap-fill layer;
performing one or more additional semiconductor processing steps; and
heating said gap-fill layer to its thermal decomposition temperature or higher and thereby removing at least some of said gap-fill layer.

2. The method of claim 1, wherein said crosslinking comprises heating said gap-fill composition at a temperature of about 160° C. to about 220° C.

3. The method of claim 1, wherein said heating said gap-fill layer comprises heating at a temperature of about 300° C. or greater for about 120 seconds to about 60 minutes.

4. The method of claim 1, wherein at least about 95% of said gap-fill layer is removed during said heating.

5. The method of claim 1, wherein said performing one or more additional semiconductor processing steps comprises:
forming a photoresist layer on said gap-fill layer or on an intermediate layer formed on said gap-fill layer; and
patterning said photoresist layer.

6. The method of claim 1, wherein said pattern is in or on a surface of a microelectronic substrate.

7. The method of claim 1, wherein said carrying out one or more additional semiconductor processing steps results in a support layer being formed on at least part of said gap-fill layer, and the removal of at least some of said gap-fill layer results in an air gap under the support layer.

8. The method of claim 7, wherein a plurality of said air gaps are formed.

9. The method of claim 1, wherein said polymer is a reversible addition fragmentation chain transfer polymer.

10. The method of claim 1, wherein said crosslinkable monomer comprises an epoxy ring.

11. The method of claim 10, wherein:
said crosslinkable monomer is chosen from one or more of glycidyl methacrylate, glycidyl acrylate, (3,4-epoxycyclohexyl)methyl acrylate, or combinations thereof, and
said second monomer is chosen from one or more of aliphatic methacrylates, benzyl methacrylate, methacrylic acid, cyclohexyl methacrylate, isopropyl methacrylate, phenyl methacrylate, or combinations thereof.

12. The method of claim 11, wherein said aliphatic methacrylate comprises methyl methacrylate.

13. The method of claim 1, wherein said polymer comprises the moiety 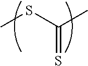
at or near an end of said polymer.

14. The method of claim 13, wherein said polymer comprises a moiety chosen from: 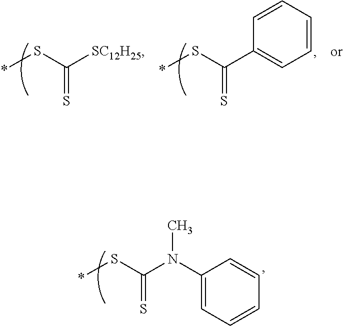
at or near an end of said polymer.

15. The method of claim 1, wherein said gaps have a width of about 50 nm or less.

16. The method of claim 1, wherein said gaps have an aspect ratio of about 2 or greater.

17. A microelectronic structure comprising:
a pattern comprising a plurality of gaps; and
a gap-fill composition in at least some of said gaps, said gap-fill composition comprising a polymer comprising:
a first recurring monomer chosen from glycidyl methacrylate, glycidyl acrylate, (3,4-epoxycyclohexyl)methyl acrylate, or combinations thereof;
a second recurring monomer chosen from methyl methacrylate, benzyl methacrylate, methacrylic acid, cyclohexyl methacrylate, isopropyl methacrylate, phenyl methacrylate, or combinations thereof; and
a moiety at or near one end of said polymer, said moiety comprising

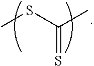

18. The microelectronic structure of claim 17, wherein said polymer comprises a terminal monomer including one or both of the moieties:

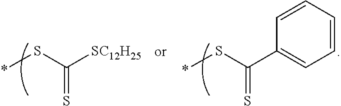

19. The microelectronic structure of claim 17, wherein said first recurring monomer is crosslinked so that said gap-fill composition is a gap-fill layer.

20. The microelectronic structure of claim 19, further comprising one or more additional layers on said gap-fill layer.

21. The microelectronic structure of claim 17, wherein said gaps have a width of about 50 nm or less.

22. The microelectronic structure of claim 17, wherein said gaps have an aspect ratio of about 2 or greater.
